(19) United States
(12) Patent Application Publication
(10) Pub. No.: US 2015/0136372 A1
(43) Pub. Date: May 21, 2015

(54) COLD PLATE FOR ELECTRONICS COOLING

(71) Applicant: Jonathan A. Sherbeck, Tempe, AZ (US)

(72) Inventor: Jonathan A. Sherbeck, Tempe, AZ (US)

(73) Assignee: Arizona Board of Regents on behalf of Arizona State University, Scottsdale, AZ (US)

(21) Appl. No.: 14/577,550

(22) Filed: Dec. 19, 2014

Related U.S. Application Data
(63) Continuation of application No. PCT/US2013/052252, filed on Jul. 26, 2013.
(60) Provisional application No. 61/676,719, filed on Jul. 27, 2012.

(51) Int. Cl. H05K 7/20; F28F 3/12

(52) U.S. Cl. CPC H05K 7/20254; F28F 3/12
USPC 165/170

(57) ABSTRACT

A fluid cooled cold plate can comprise a fluid output port connected near a thermally conductive base plate having a coupled heat source device, a fluid input port connected to a top surface of the cold plate, and multiple extended surface areas connected to the base plate and extending normal to the base plate. The cold plate can be configured for generally uniform fluid flow across the multiple extended surface areas. Furthermore, the multiple extended surface areas can create more resistance near a top surface of the multiple extended surface areas and less resistance near the base plate. For example, the plurality of extended surface areas can be wires that are wound near the base plate and fanned out near the top surface. An advantage of the disclosed cold plate design is the increase in heat transfer area and efficiency.

### CROSS-REFERENCE TO RELATED APPLICATIONS

This application is a continuation of PCT Application No. PCT/US2013/052252 filed on Jul. 26, 2013 and entitled “COLD PLATE FOR ELECTRONICS COOLING”. PCT Application No. PCT/US2013/052252 claims priority to, and the benefit of, U.S. Provisional Application Ser. No. 61/676,719 filed on Jul. 27, 2012 and entitled “COLD PLATE FOR ELECTRONICS COOLING”. Each of the above applications is hereby incorporated by reference in their entirety.

### FEDERALLY SPONSORED RESEARCH OR DEVELOPMENT

This invention was made with government support under grant number 0855277 awarded by the National Science Foundation. The Government has certain rights in the invention.

### TECHNICAL FIELD

The present disclosure relates to cooling of electronic components, and in particular to systems and methods related to the same.

### BACKGROUND

In the typical cold plate design, the fluid input is distributed across an array of fins. Heat flows from the device being cooled and is distributed by the base plate before being conducted into the fins. The coldest part of the fin is the tip at the entry, and the hottest part of the fin is the fin base at the exit. The coolant fluid is shown entering the left side of the fin at a uniform temperature. The finite thermal conductivity of the fin results in the tip of the fin being colder than the base, and the temperature of the fluid varies accordingly with the flow at the tip being colder than the base. This characteristic limits the ability of the heat transfer to be increased by adding height to the fin.

Typical cross flow cold plate design is limited in heat exchange performance due to fin efficiency. Fin efficiency results from the finite thermal conductivity of the fin. The tip of the fin has a lower temperature than the base, which results in a temperature gradient at the exit, and limits performance. Accordingly, improved cold plates remain desirable, particularly in light of increasing thermal dissipation in electronic devices.

### SUMMARY

In accordance with various embodiments, a fluid cooled cold plate can comprise a fluid output port connected near a thermally conductive base plate, wherein a heat source device is coupled to the base plate, a fluid input port connected to a top surface of the cold plate, and a plurality of extended surface areas connected to the base plate and extending normal to the base plate. The cold plate can be configured for generally uniform fluid flow across the plurality of extended surface areas. Furthermore, the plurality of extended surface areas can create more resistance near a top surface of the plurality of extended surface areas and less resistance near the base plate. For example, the plurality of extended surface areas can be wires that are wound near the base plate and fanned out near the top surface.

An advantage of the disclosed cold plate design is the increase in heat transfer area and efficiency. The disclosed cold plate design results in the average temperature of the output flow approaching the temperature of the base plate more closely than a prior art cold plate design. Furthermore, in various embodiments, there is a substantially reduced temperature difference between the fluid and plurality of extended surfaces areas from the base plate to the top surface. In other words, in various embodiments, the temperature difference between the fluid temperature and the temperature of the plurality of extended surface areas is substantially constant in the cold plate from the top surface to the base plate.

### BRIEF DESCRIPTION OF THE DRAWINGS

With reference to the following description and accompanying drawings:

FIGS. 1A-1C illustrate exemplary cold plates in accordance with various embodiments;

FIG. 2 illustrates an exemplary uniform fluid flow through a cold plate in accordance with various embodiments;

FIG. 3 illustrates an exemplary wire extended surface area with a fanned out end in accordance with various embodiments;

FIG. 4A illustrates a heat transfer curve of a prior art cold plate;

FIG. 4B illustrates a heat transfer curve of an exemplary cold plate in accordance with various embodiments;

FIG. 5A illustrates multiple wire extended surface areas forming tunnels in accordance with various embodiments;

FIG. 5B illustrates multiple fin extended surface areas forming tunnels in accordance with various embodiments;

FIGS. 6A-6B illustrate multiple wire extended surface areas and a sleeve forming tunnels in accordance with various embodiments;

FIG. 7A illustrates twisted finstock for a cold plate in accordance with various embodiments; and

FIG. 7B illustrates combed finstock welded together at the base for a cold plate in accordance with various embodiments.

### DETAILED DESCRIPTION

The following description is of various exemplary embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments without departing from principles of the present disclosure.

For the sake of brevity, conventional techniques for electronics cooling and the like may not be described in detail herein. Furthermore, the connecting lines shown in various figures contained herein are intended to represent exemplary functional relationships and/or physical couplings between various elements. It should be noted that many alternative or additional functional relationships or physical connections may be present in a practical cooling system, for example a cold plate.

As compared to prior cold plates, a cold plate configured in accordance with principles of the present disclosure allows a drastic increase in heat transfer area, and obviates the problem of fin efficiency. Moreover, in various exemplary embodiments, the fluid flow goes from the tip of the fins to the base plate, and is very uniform across the area to be cooled.

Compared to a well-developed commercial cold plate, an exemplary cold plate configured in accordance with principles of the present disclosure has about 23.5 times the heat transfer area per square inch of the footprint, with the potential for further gains in both heat transfer area and the heat transfer coefficient. Accordingly, exemplary cold plates configured in accordance with principles of the present disclosure permit cooling of electronic devices with high power dissipation.

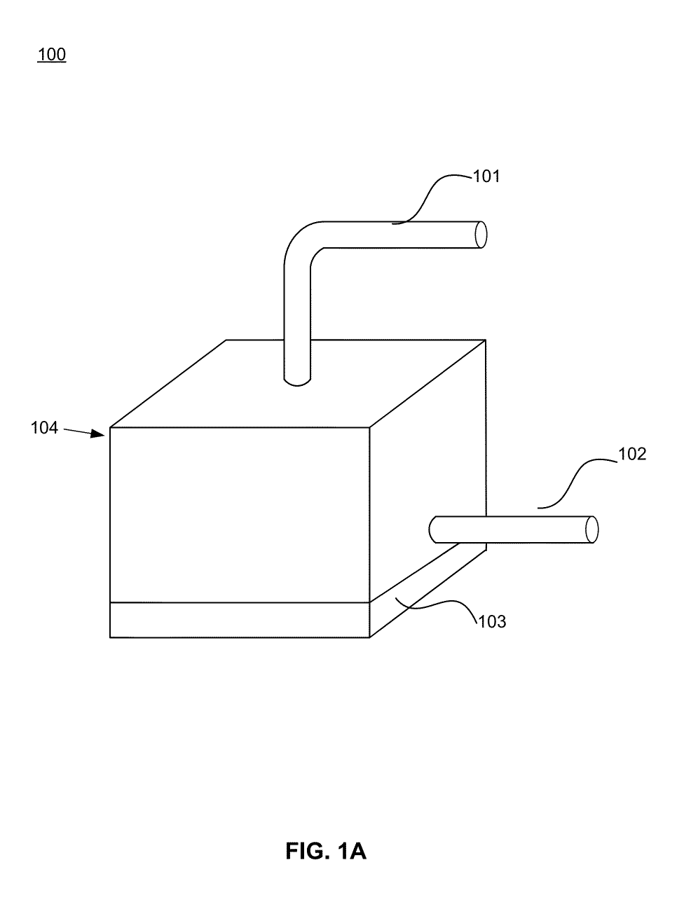

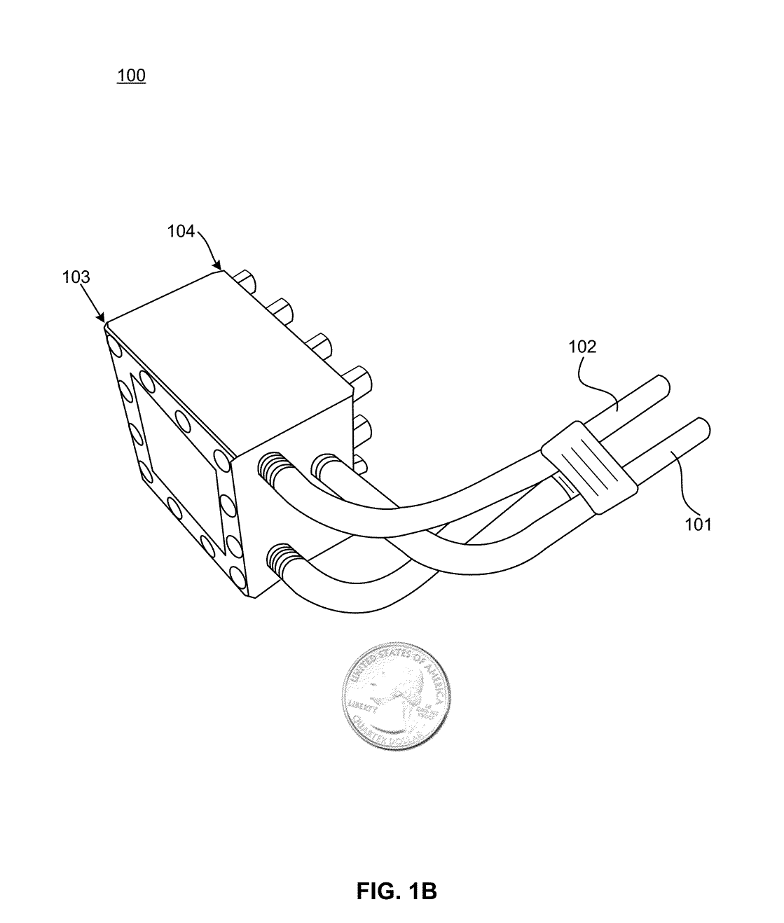

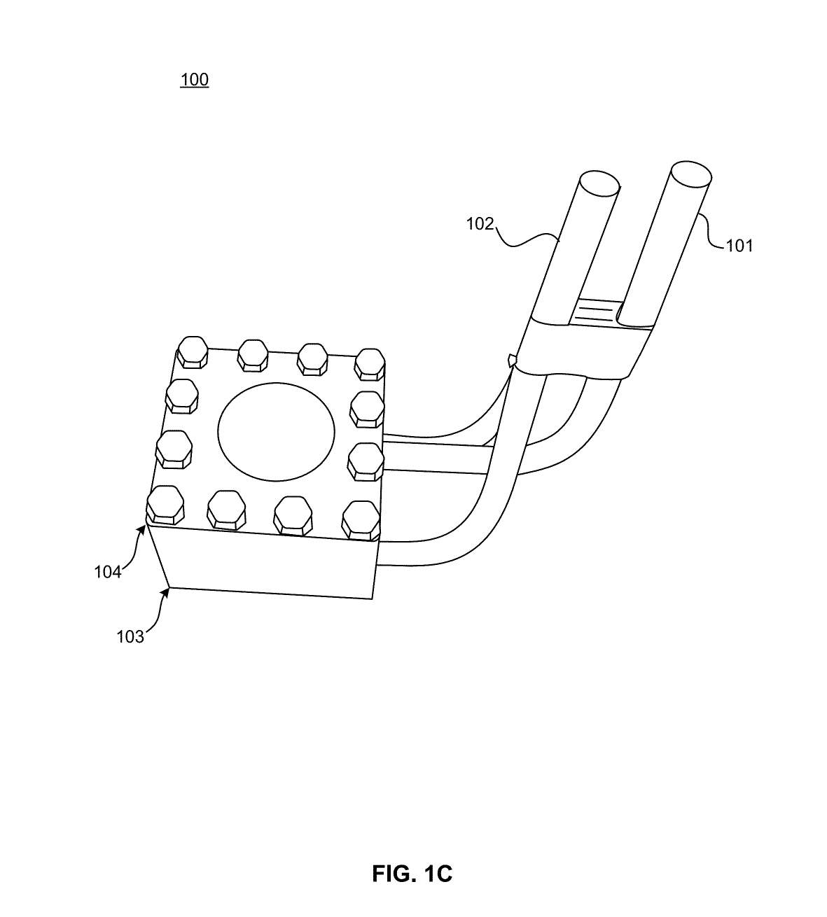

In accordance with various embodiments and with reference to FIGS. 1A-1C, a fluid cooled cold plate 100 can comprise a fluid input port 101 and fluid output port 102. In various embodiments, the cold plate 100 can comprise one or more fluid input ports 101 and one or more fluid output ports 102. The fluid output port can be connected near a thermally conductive base plate 103, where a heat source device can be coupled to the base plate 103. The fluid input port 101 can be connected to a top surface 104 of the cold plate 100 and normal to the base plate 103. In another embodiment, the fluid input port 101 can be connected to the side of cold plate 100 near the top surface 104 and parallel to the base plate 103.

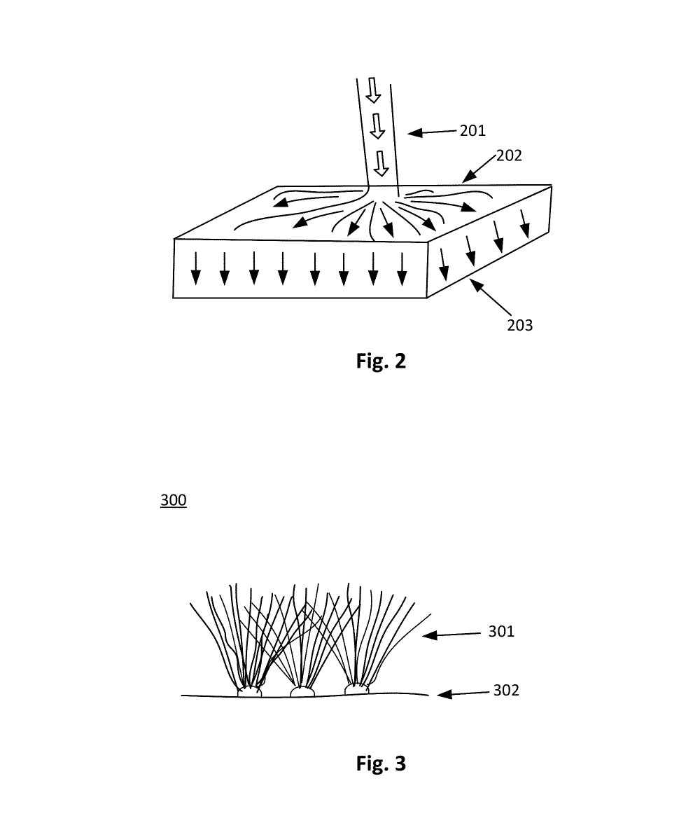

A plurality of extended surface areas, such as fins or wires, may be connected to the base plate and extend normal to the base plate. The fluid from the input port first makes contact with the portion of the extended surface area that is farthest from the base plate. As illustrated by FIG. 2, the extended surface areas can be formed such that the incoming fluid 201 encounters resistance near the input port and spreads across the entire surface area 202 of the extended surface areas before moving downward towards the base plate 203. The cold plate can be configured for generally uniform fluid flow across the plurality of extended surface areas.

Furthermore, in various embodiments and with reference to FIG. 3, the extended surface area 300 is more fluid resistant near the top surface 301 of the surface area and less resistance near the base plate 302. For example, the extended surface areas may include wire bunches as the extended surface areas. The wire bunches can fan out near the top surface 301 of the surface areas, and can be welded together near the base plate 302. The fanned out portion near the top surface 301 can create the initial resistance for the fluid flow. The welded portions near the base plate 302 can create tunnels with low resistance to create traverse fluid flow.

The advantage of the disclosed cold plate design is the increase in heat transfer area and efficiency. The disclosed cold plate design may result in the average temperature of the output flow approaching the temperature of the base plate more closely than a prior art cold plate design. Furthermore, in various example embodiments, there is substantially no temperature gradient between the fluid and plurality of extended surfaces areas from the base plate to the top surface. In other words, in various example embodiments, the temperature difference between the fluid temperature and the temperature of the plurality of extended surface areas is substantially constant in the cold plate from the top surface to the base plate.

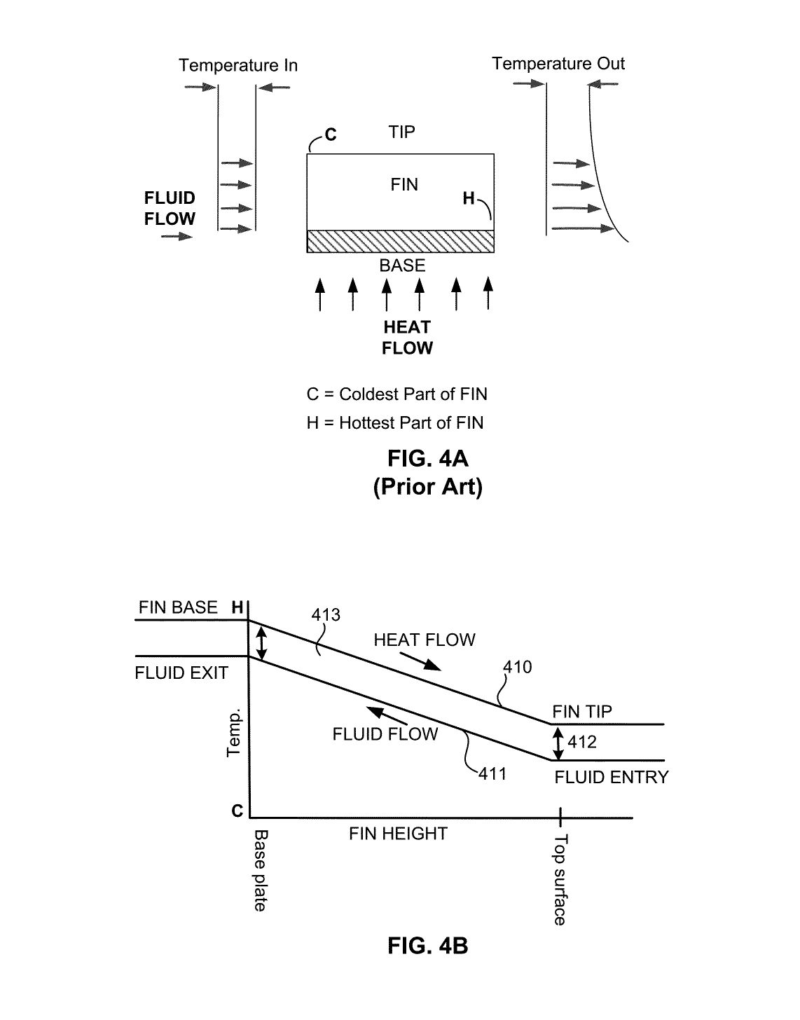

FIG. 4A illustrates in a typical prior art cold plate design and the difference the in the fluid temperature gradients at the input and the output. In the typical cold plate design, the fluid input is across the base plate and perpendicular to the heat flow. The fluid temperature gradient at the input is substantially constant, and the fluid temperature gradient at the output is such that the fluid flowing closer to the base plate is at a higher temperature compared to the fluid flowing across the top surface. As illustrated in FIG. 4A, a typical prior art cold plate has is a temperature gradient along the length of the base which means the cooling power varies from inlet to exit, and along the height of the fin, which results in a temperature gradient in the exiting fluid flow.

In contrast and with reference to FIG. 4B, in various embodiments the flow of the fluid is from the top surface towards the base plate, which is countercurrent to the heat being conducted up through the fin. In other words, the fluid input is near the top surface, such that when the fluid is at its coolest temperature, the fluid is injected into the coolest part of the cold plate near the top surface. The temperature of the cold plate fin 410 along length from the base plate to the top surface decreases from the hottest (H) temperature towards a cooler temperature. Likewise, the temperature of the fluid 411 along the length from the top surface to the base plate increases from the coldest (C) temperature towards a hotter temperature. The initial temperature difference between the cold plate fin temperature 410 and the fluid temperature 411 at the top surface is designated by 412. Similarly, the resulting temperature difference between the cold plate fin temperature 410 and the fluid temperature 411 at the base plate is designated by 413.

The efficiency of the cold plate design disclosed herein can be understood by comparing

FIGS. 4A and 4B. First, in accordance with various embodiments, the temperature difference between the cold plate fin temperature 410 and the fluid temperature 411 in the exemplary embodiment is substantially constant in the cold plate. In other words, the temperature difference at 412 is substantially the same as the temperature difference at 413, and substantially the same throughout the cold plate.

In addition to the countercurrent flow design of the cold plate, the uniformity of the flow is another important feature. As briefly discussed above with respect to FIG. 3, the wire bunches can be fanned out near the top surface 301 of the surface areas, and can be welded together near the base plate 302 in order to create more fluid resistance near the top surface and less resistance near the base plate. The increased resistance at the top surface is designed to spread the fluid across the top surface before moving downwards towards the base plate, as illustrated in FIG. 2. The resulting uniformity of flow is advantageous in comparison to a prior art cold plate design, which can result in uneven heat transfer.

The wires making up one of the extended surface embodiments is stranded wire and can have different shaped cross-sections, such as a round, square, or any other shape. The different shaped cross-section may be selected in order to increase or decrease the agitation of the fluid flowing through the cold plate. The wire material can be any material that holds its shape under the fluid flow and temperature conditions of the cold plate. For example, the wire material may be made of copper, aluminum, carbon, or other high thermal conductivity material.

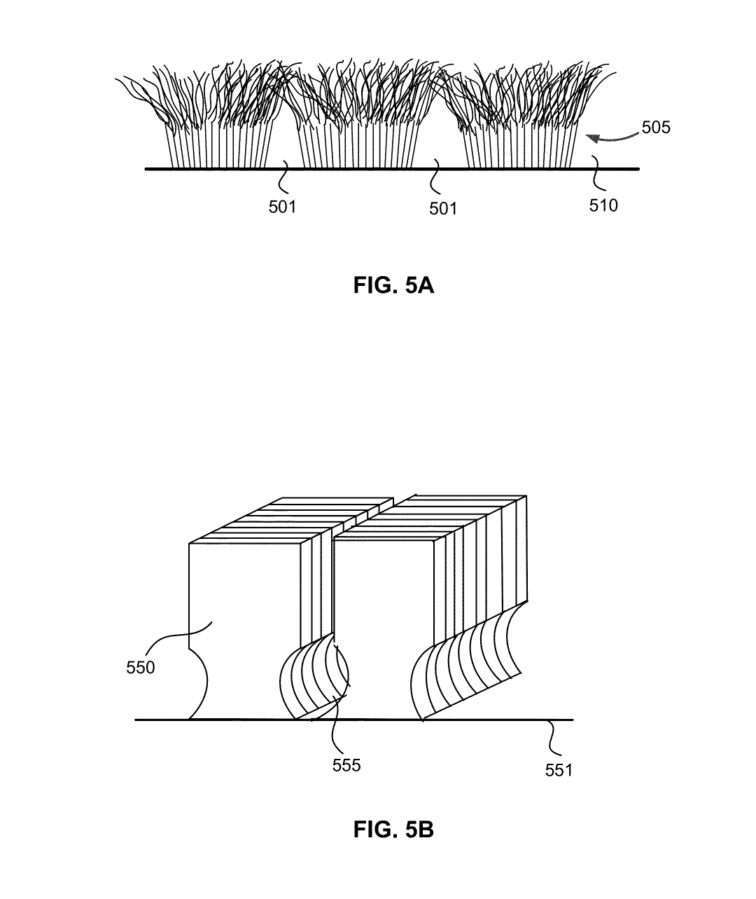

As the extended surface areas approach the base plate, various tunnel-like structures may be formed in accordance with various embodiments. The multiple extended surface areas create a tunnel for fluid flow near the base plate. The extended surface areas can form the tunnels 501 resulting from wires 505 remaining wound and attached to the base plate 510, as illustrated in FIG. 5A. In other embodiments, the extended surface areas can comprise fins 550 that narrow towards the base plate 551 attachment and are wider near the top surface to create tunnels 555, as illustrated in FIG. 5B. The adjacent extended surface areas can form the sides of each tunnel and a surface of the base plate forms the floor of each tunnel. As illustrated in both FIGS. 5A and 5B, the multiple extended surface areas can be comprised of either wires or fins extending away from the base plate in a generally perpendicular direction to the plane of the base plate.

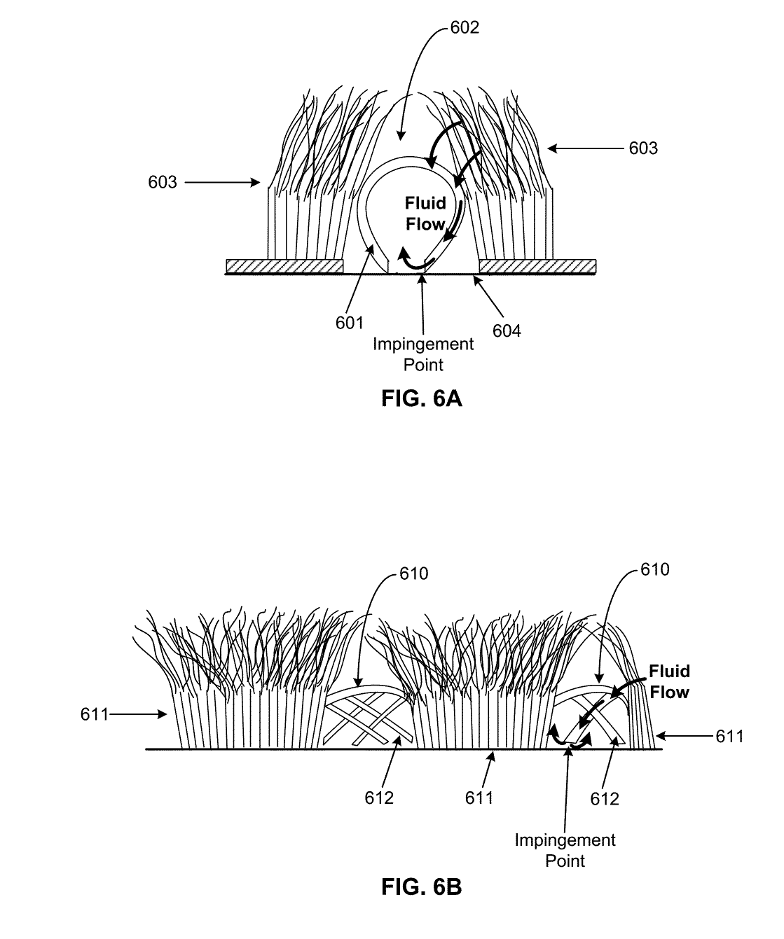

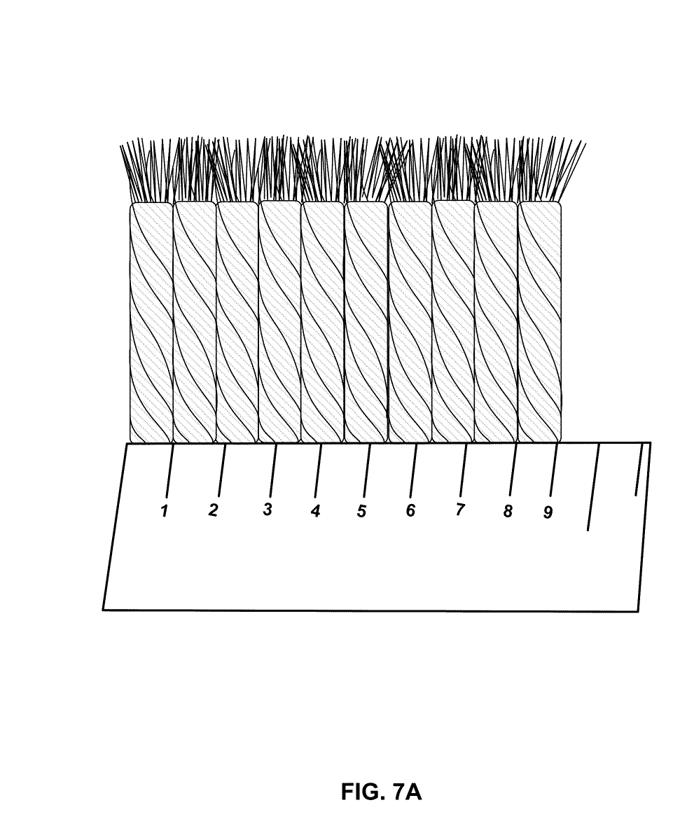

Moreover, in accordance with various embodiments and with reference to FIG. 6A, the formed tunnels in the cold plate can also comprise an additional structure designed to direct flow exiting the finstock to cool the base plate by impingement before exiting through the tunnel. For example, a sleeve 601 can be inserted in a tunnel 602 to prevent the fluid from flowing in between the extended surface areas 603 too quickly. The sleeve 601 can have a corrugated structure which funnels the fluid around the sides of the sleeve 601 and past the connecting point between the extended surface area 603 and the base plate 604 and into the tunnel 602 area inside the sleeve 601. Furthermore, in various embodiments and with reference to FIG. 6B, the sleeve 610 can be attached to the extended surface areas 611 and not have an area formed between the sleeve 610 and the extended surface area 611. In this embodiment, the sleeve 611 can comprise multiple holes or tubular inlets 612 configured to funnel the fluid into the area inside the sleeve 601 after impinging on the base plate 609. For example, sleeve 611 can have a tubular inlet on the inside of the sleeve that forms an opening at the outside surface of sleeve 611. The fluid flows down the extended surface areas and can be funneled into the tubular inlets, such that the fluid is directed into the base plate surface.

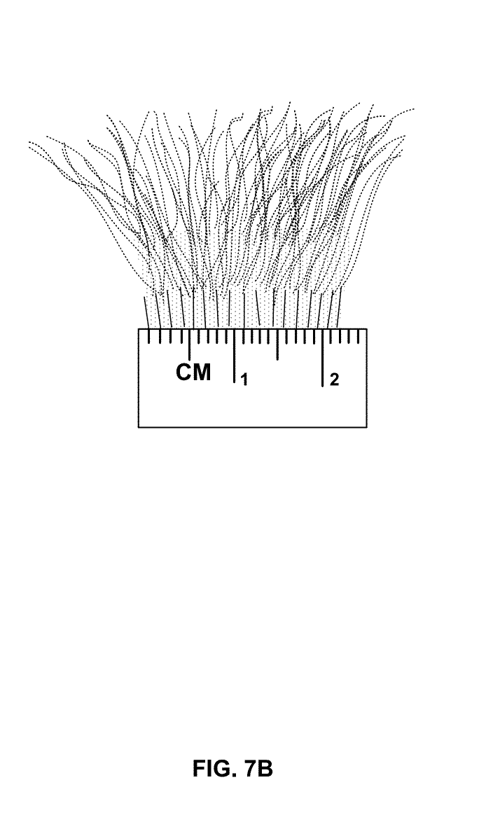

In order to provide additional understanding, more specific examples of the cold plate and extended surface areas will be described. These examples are merely for illustration and are not meant to be limiting. In an exemplary embodiment, with reference now to FIG. 7A, an exemplary cold plate is constructed using copper wire consisting of seven twisted strands, with each strand having 63 pieces of 40 gauge wire. Ten pieces of this wire may be clamped hard together in a clamp that holds the wire pieces in a length of approximately 0.875 inches. The wires may be infused with argon and bonded together at the base. The wires may be cut close to the clamp with a specially sharpened end cutter, and the cut ends may be fused together with a TIG welder.

A round weld bead results from the above process, which may be filed down to a flat surface that may be soldered to a base plate, for example with a 96.5% tin, 3.5% silver solder paste. The welded wires may be removed from the fixture and cut off at a length of approximately 0.750 inches.

With reference to FIG. 7B, the cut off strip of finstock may be prepared for assembly to the base plate by combing out all the twisted strands to yield a brush. The base plate may be a copper sheet, for example a 0.016 inch thick copper sheet having a size of 1.75 inches square. In various embodiments, an aluminum fixture may be used to compress thirteen strips of finstock into a 0.875 inch by 1.25 inch area centered on the base plate. Using thirteen strips results in a nominal fin count of 57,330. A higher or lower number of strips may be used in different embodiments, for example in order to achieve a desired density.

Additionally, in various embodiments, steel wool may be used as a spring to force the strips of finstock onto the base plate for soldering. The solder operation may be performed by baking the fixture at high heat, for example at approximately 450 degrees Fahrenheit for about one hour.

Furthermore, a case for an exemplary cold plate may be made from a 1.75 inch square of 1 inch thick G10 epoxy/fiberglass composite. A cavity having the dimensions of 0.875 inches wide, 1.25 inches long, and 0.875 inches deep may be centered on the bottom of the G10 block. In this configuration, a plenum of about 0.125 inches deep is provided above the finstock where the coolant may be delivered.

Where the finstock is welded together at the base, the wires are held together, whereas above that, the combed out wire brush is much more bulky. With momentary reference to FIGS. 5A and 5B, this results in tunnels across the bottom of the finstock assembly where flow is collected to exit the cold plate. Because the flow resistance in the bulk of the finstock assembly is much greater than through the tunnels, the flow is very uniform across the face of the cold plate assembly. Uniform flow has been confirmed experimentally, for example by taking an infrared video of the cold plate surface while alternately flowing hot and cold water through the cold plate.

In an exemplary embodiment, the cold plate assembly comprises the G10 case, a gasket of Fel-Pro P/N 3157 1/32 inch thick Rubber-Fiber sheet, the baseplate with the finstock soldered to it, and a clamp plate of 0.032 inch thick brass. The gasket and clamp plate are 1.75 inches square with one 1.25 inch square cut from the center. All of the parts have four holes per side drilled on 0.50 inch centers. The base plate holes are countersunk to receive 0.75 inch long 4-40 screws, and long blind nuts made from 0.25 inch brass hex stock may be utilized with the screws.

The gasket establishes a 0.03125 inch gap between the bottom of the case and the base plate where the coolant exits by flowing up through five 0.0625 inch diameter holes drilled on 0.20 inch centers on each side to a 0.125 inch hole located 0.25 inch from the bottom and 0.30 inch from each side. The film and the ten 0.0625 inch holes help keep the flow uniform. A 0.125 inch hole centered and 0.1875 inched from the top supplies the plenum over the finstock. Copper tube of 0.25 inch diameter turns the flow from and to vertical.

The two exit flows can be combined into one via a two-into-one manifold. The entry and exits are epoxied into the case, and can be held together with a balsa block that is lashed in place with Kevlar 49 from E.I. DuPont and epoxy. The finstock may be inserted into the case by tightly winding it with dental floss that spiraled up from the base plate, and slowly unwinding it from the finstock as the finstock is pushed into the case. In various exemplary embodiments, finstock having a density of 50% or more may be utilized and inserted into the case in a similar manner.

In various exemplary embodiments, testing of a cold plate configured in accordance with principles of the present disclosure as compared to a Coolit brand Eco commercial cold plate showed an increase in heat capture of about 70%.

### EXAMPLE EMBODIMENTS

1. A fluid cooled cold plate comprising:
a fluid output port connected near a thermally conductive base plate, wherein a heat source device is coupled to the base plate;
a fluid input port connected to a top surface of the cold plate;
a plurality of extended surface areas connected to the base plate and extending normal to the base plate;
wherein the cold plate is configured for generally uniform fluid flow across the plurality of extended surface areas.

2. The cold plate of claim 1, wherein the plurality of extended surface areas create more flow resistance near a top surface of the plurality of extended surface areas in comparison to the flow resistance across the base plate.

3. The cold plate of any of claim 1 or 2, wherein the plurality of extended surface areas are welded together near the base plate and fan out towards the top surface.

4. The cold plate of claim 3, wherein the wires are at least one of round wires or square wires.

5. The cold plate of any of claims 1-4, wherein the average temperature of the output flow approaches the temperature of the base plate.

6. The cold plate of any of claims 1-5, wherein the plurality of extended surface areas create a tunnel for transverse fluid flow near the base plate.

7. The cold plate of claim 6, wherein adjacent extended surface areas of the plurality of extended surface areas form the sides of each tunnel and a surface of the base plate forms the floor of each tunnel.

8. The cold plate of any of claims 1-7, wherein there is substantially reduced temperature difference between the fluid and plurality of extended surfaces areas from the base plate to the top surface.

9. The cold plate of any of claims 1-7, wherein the temperature difference between the fluid temperature and the temperature of the plurality of extended surface areas is substantially constant in the cold plate.

10. The cold plate of any of claims 1-9, wherein the plurality of extended surface areas comprises a plurality of wires extending away from the base plate in a generally perpendicular direction to the plane of the base plate.

11. The cold plate of any of claims 1-10, wherein the fluid input port is perpendicular to the base plate.

12. The cold plate of any of claims 1-10, wherein the fluid input port is parallel to the base plate.

13. The cold plate of claim 7, further comprising a sleeve in the tunnel, wherein the sleeve is connected to the adjacent extended surface areas of the plurality of extended surface areas.

14. The cold plate of claim 13, wherein the sleeve is made of a corrugated structure for funneling the fluid flow into the tunnel.

15. The cold plate of claim 13, wherein the sleeve comprises multiple tubular inlets configured to funnel the fluid into an area inside the sleeve.

16. A method comprising:
injecting, through a fluid input port of a fluid cooled cold plate, a fluid flow normal to a thermally conductive base plate, wherein the fluid input port is near a top surface of the cold plate and away from the base plate;
diverting the fluid flow across a top surface of a plurality of extended surface areas, wherein the fluid flow moves down the plurality of extended surface areas in a substantially uniform manner; and
removing, through a fluid output port located near the base plate, the fluid flow.

17. The method of claim 16, further comprising creating more fluid resistance for the fluid flow near a top surface of the plurality of extended surface areas in comparison to the fluid resistance for the fluid flow near the base plate.

18. The method of claim 16 or 17, wherein the plurality of extended surface areas comprises wires that are wound near the base plate and fanned out near the top surface.

19. The method of claim 18, wherein the wires are at least one of round wires or square wires.

20. The method of any of claims 16-19, wherein the average temperature of the output flow approaches the temperature of the base plate.

21. The method of any of claims 16-20, wherein the plurality of extended surface areas create a tunnel for fluid flow near the base plate.

22. The method of claim 21, wherein adjacent extended surface areas of the plurality of extended surface areas form the sides of each tunnel and from a surface of the base plate forms the floor of each tunnel.

23. The method of any of claims 16-22, wherein there is substantially reduced temperature difference between the fluid and plurality of extended surfaces areas from the base plate to the top surface.

24. The method of any of claims 16-22, wherein the temperature difference between the fluid temperature and the temperature of the plurality of extended surface areas is substantially constant in the cold plate.

25. The method of claim 16, wherein the plurality of extended surface areas comprises a plurality of wires extending away from the base plate in a generally perpendicular direction to the plane of the base plate.

It will be appreciated by those skilled in the art that a cold plate configured in accordance with principles of the present disclosure may be utilized for various applications, and the foregoing examples are by way of illustration and not of limitation.

While the principles of this disclosure have been shown in various embodiments, many modifications of structure, arrangements, proportions, the elements, materials and components, used in practice, which are particularly adapted for a specific environment and operating requirements may be used without departing from the principles and scope of this disclosure. These and other changes or modifications are intended to be included within the scope of the present disclosure.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, required, or essential feature or element.

As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Also, as used herein, the terms “coupled,” “coupling,” or any other variation thereof, are intended to cover a physical connection, an electrical connection, a magnetic connection, an optical connection, a communicative connection, a functional connection, and/or any other connection.

What is claimed is:

1. A fluid cooled cold plate comprising:
a fluid output port connected near a thermally conductive base plate, wherein a heat source device is coupled to the base plate;
a fluid input port connected to a top surface of the cold plate;
a plurality of extended surface areas connected to the base plate and extending normal to the base plate;
wherein the cold plate is configured for generally uniform fluid flow across the plurality of extended surface areas.

2. The cold plate of claim 1, wherein the plurality of extended surface areas create more flow resistance near a top surface of the plurality of extended surface areas in comparison to the flow resistance across the base plate.

3. The cold plate of claim 1, wherein the plurality of extended surface areas are welded together near the base plate and fan out towards the top surface.

4. The cold plate of claim 3, wherein the wires are at least one of round wires or square wires.

5. The cold plate of any of claims 1-4, wherein the average temperature of the output flow approaches the temperature of the base plate.

6. The cold plate of claim 3, wherein the plurality of extended surface areas create a tunnel for transverse fluid flow near the base plate.

7. The cold plate of claim 6, wherein adjacent extended surface areas of the plurality of extended surface areas form the sides of each tunnel and a surface of the base plate forms the floor of each tunnel.

8. The cold plate of claim 1, wherein there is substantially reduced temperature difference between the fluid and plurality of extended surfaces areas from the base plate to the top surface.

9. The cold plate of claim 1, wherein the temperature difference between the fluid temperature and the temperature of the plurality of extended surface areas is substantially constant in the cold plate.

10. The cold plate of claim 1, wherein the plurality of extended surface areas comprises a plurality of wires extending away from the base plate in a generally perpendicular direction to the plane of the base plate.

11. The cold plate of claim 10, wherein the fluid input port is perpendicular to the base plate.

12. The cold plate of claim 10, wherein the fluid input port is parallel to the base plate.

13. The cold plate of claim 7, further comprising a sleeve in the tunnel, wherein the sleeve is connected to the adjacent extended surface areas of the plurality of extended surface areas.

14. The cold plate of claim 13, wherein the sleeve is made of a corrugated structure for funneling the fluid flow into the tunnel.

15. The cold plate of claim 13, wherein the sleeve comprises multiple tubular inlets configured to funnel the fluid into an area inside the sleeve.

16. A method comprising:
injecting, through a fluid input port of a fluid cooled cold plate, a fluid flow normal to a thermally conductive base plate, wherein the fluid input port is near a top surface of the cold plate and away from the base plate;
diverting the fluid flow across a top surface of a plurality of extended surface areas, wherein the fluid flow moves down the plurality of extended surface areas in a substantially uniform manner; and
removing, through a fluid output port located near the base plate, the fluid flow.

17. The method of claim 16, further comprising creating more fluid resistance for the fluid flow near a top surface of the plurality of extended surface areas in comparison to the fluid resistance for the fluid flow near the base plate.

18. The method of claim 16, wherein the plurality of extended surface areas comprises wires that are wound near the base plate and fanned out near the top surface.

19. The method of claim 18, wherein the wires are at least one of round wires or square wires.

20. The method of claim 16, wherein the average temperature of the output flow approaches the temperature of the base plate.

21. The method of claim 18, wherein the plurality of extended surface areas create a tunnel for fluid flow near the base plate.

22. The method of claim 21, wherein adjacent extended surface areas of the plurality of extended surface areas form the sides of each tunnel and from a surface of the base plate forms the floor of each tunnel

23. The method of any of claims 16-22, wherein there is substantially reduced temperature difference between the fluid and plurality of extended surfaces areas from the base plate to the top surface.

24. The method of any of claims 16-22, wherein the temperature difference between the fluid temperature and the temperature of the plurality of extended surface areas is substantially constant in the cold plate.

25. The method of claim 16, wherein the plurality of extended surface areas comprises a plurality of wires extending away from the base plate in a generally perpendicular direction to the plane of the base plate.
